(19) United States
(12) Patent Application Publication
(10) Pub. No.: US 2004/0235240 A1
(43) Pub. Date: Nov. 25, 2004

(54) Method of fabricating memory device with vertical transistors and trench capacitors

(75) Inventors: Yu-Sheng Hsu, Taoyuan (TW); Yi-Nan Chen, Taipei (TW); Ming-Cheng Chang, Taoyuan Hsien (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/639,986

(22) Filed: Aug. 13, 2003

(30) Foreign Application Priority Data
May 23, 2003 (TW) 92113960

(51) Int. Cl. H01L 21/8242

(52) U.S. Cl. 438/239; 438/243

(57) ABSTRACT

A method for fabricating a memory device with a vertical transistor and a trench capacitor. First, a capacitor is formed in a lower portion of a trench formed in a substrate. Next, a wiring structure and a first trench top isolation layer are successively formed overlying the capacitor. Next, a dielectric spacer is formed over the sidewall of the trench and overlying the first trench top isolation layer. Thereafter, the first trench top isolation layer is removed to expose the sidewall of the trench between the dielectric spacer and the wiring structure. Next, a buried strap is formed in the substrate around the exposed sidewall of the trench. Thereafter, the dielectric spacer is removed. Next, a second trench top isolation layer is formed overlying the wiring structure. Finally, a control gate is formed overlying the second trench top isolation layer.

### BACKGROUND OF THE INVENTION

1. Field of the Invention

The present invention relates in general to a method of fabricating a memory device, and more particularly, to a method of fabricating a memory device with vertical transistors and trench capacitors.

2. Description of the Related Art

In the rapidly evolving integrated circuit industry there is a development tendency toward high performance, miniaturization, and high operating speed. Additionally dynamic random access memory (DRAM) fabrication methods have developed rapidly.

Typically, current DRAM cells include a transistor and a capacitor. Since the capacity of current DRAM has reached 256 MB and up to 512 MB, the size of memory cells and transistors has narrowed to meet demands for high integration, higher memory capacity and higher operating speeds. In conventional planar transistor technology, however, more useable surface area on a chip is required, and it is difficult to meet the previously mentioned demands. Accordingly, vertical transistor technology has been applied to DRAM fabrication with the goal of reducing the area occupied by the transistor and the capacitor on the semiconductor substrate. The conventional planar transistor technology requires a large amount of surface area on the chip, and cannot accomplish the demand for high integration. Conversely, vertical transistor technology can improve upon the disadvantages of the conventional semiconductor memory cell, and is positioned to become a major semiconductor memory cell fabrication method.

With the decreasing size of transistors, however, buried straps which serve as a transistor drain region and electrically connect the vertical transistor and the trench capacitor between neighboring trenches, may merge, as shown in FIG. 1. The buried strap is formed by thermally diffusing high concentration ions doped in the conductive layer 12 of the wiring structure 16 of the memory cell into the substrate 10 through the lightly doped or undoped conductive layer 14. This is called buried strap out-diffusion. If the diffusion area of the buried strap 18 is excessive, the merging of buried straps 18 between neighboring trenches may result, inducing shorts in the semiconductor memory device.

The conventional method for fabricating a memory device with a vertical transistor and a trench capacitor includes the following steps. A trench top isolation layer 20 is first formed and then the buried strap 18 is formed by thermal diffusion. In order to have an excellent electrical connection between the vertical transistor and the trench capacitor, however, the diffusion area of the buried strap 18 must have a diameter larger than the thickness of the trench top isolation layer 20 to suitably connect the control gate 22 and the wiring structure 16. Therefore, increased thermal diffusion temperature is required and the dosage in the conductive layer 12 must also be increased. The diffusion area of the buried strap 18, however, may increase, and as a result the buried straps 18 may merge.

### SUMMARY OF THE INVENTION

Accordingly, an object of the present invention is to provide a method for fabricating a memory device with a vertical transistor and a trench capacitor, which can prevent the merging of buried straps which provide electrical connection between neighboring trenches, from causing shorts in the memory device.

Another object of the present invention is to provide a method for fabricating a memory device with a vertical transistor and a trench capacitor, which can further decrease the size of the memory device.

Still another object of the present invention is to provide a method for fabricating a memory device with a vertical transistor and a trench capacitor, which provides excellent control for electrical connection between the vertical transistor and the trench capacitor.

The invention is characterized by modifying the formation sequence of the buried strap and the trench top isolation layer, wherein the buried strap is formed first to connect the vertical transistor to the trench capacitor, and the trench top isolation layer is then formed. Here, the buried strap can be formed by gas phase doping (GPD), instead of the conventional thermal diffusion method, and the diffusion path of GPD is defined by a trench top isolation layer and a dielectric spacer. The buried strap formed by this method offers simpler control of the ion diffusion area than that offered by conventional thermal diffusion using a doped conductive layer, and the diameter of the diffusion area of the buried strap can be reduce by one half compared to the conventional method. Moreover, the buried strap is formed first, thereby first defining the electrical connection area between the vertical transistor and the trench capacitor. In addition, the buried strap formed by GPD can reduce the annealing time compared to the conventional thermal diffusion, even without annealing to reduce the thermal budget.

In order of achieve the above objects and other advantages, a method for fabricating a memory device with a vertical transistor and a trench capacitor is provided. First, a substrate in which at least one trench is formed therein is provided. Next, a capacitor is formed in a lower portion of the trench. Next, a wiring structure is formed overlying the capacitor, and then a first trench top isolation layer is formed overlying the wiring structure. Next, a dielectric spacer is formed over the sidewall of the trench and overlying the first trench top isolation layer. Thereafter, the first trench top isolation layer is removed to expose the sidewall of the trench between the dielectric spacer and the wiring structure. A buried strap is subsequently formed in the substrate around the exposed sidewall of the trench using the dielectric spacer as a mask to serve as a drain region. Next, the dielectric spacer is removed, and then a second trench top isolation layer is formed overlying the wiring structure. Finally, a control gate is formed overlying the second trench top isolation layer, wherein the control gate is insulated from the wiring structure by the second trench top isolation layer.

### DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-section showing a conventional memory device with vertical transistors and trench capacitors where merging of buried straps occurs.

FIGS. 2 to 6 are cross-sections showing a method for forming a memory device with a vertical transistor and a trench capacitor according to the invention.

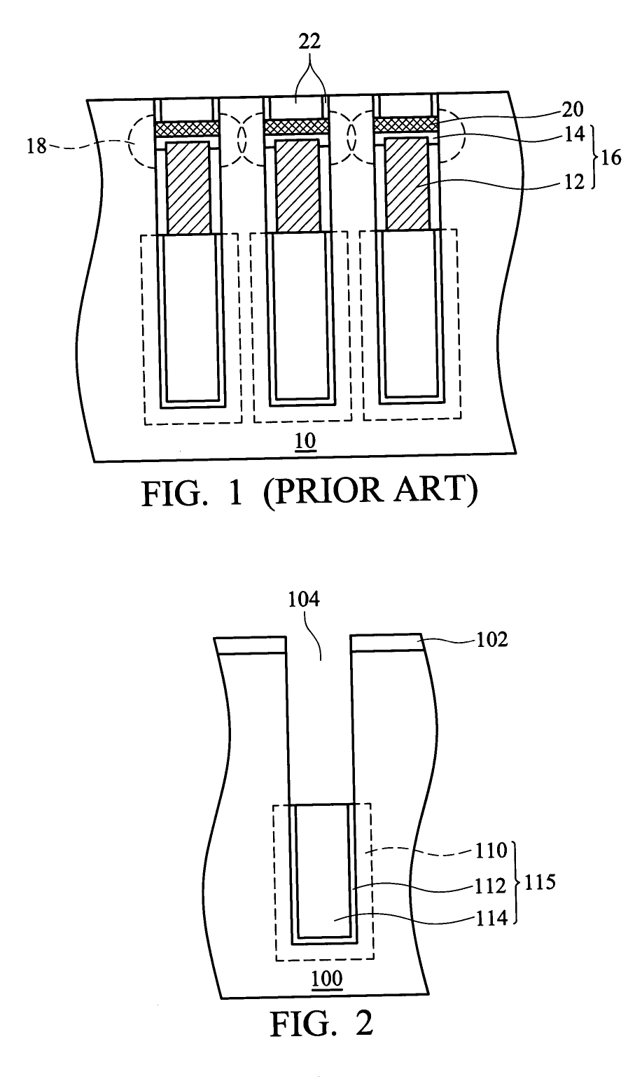

### DETAILED DESCRIPTION OF THE INVENTION

FIGS. 2 to 6 are cross-sections showing a method for forming a memory device with a vertical transistor and a trench capacitor. First, in FIG. 2, a substrate 100, such as a silicon substrate, is provided. A masking layer 102 is formed on the substrate 100. The masking layer 103 can comprise a pad oxide layer and an overlying silicon nitride layer and have a matrix pattern therein to expose regions for trench definition. Thereafter, etching is performed to transfer the pattern in the masking layer 102 on the substrate 100 to form trenches therein. In order to simplify the diagram, only one trench labeled 104 is depicted.

Next, a trench capacitor 115 is formed in a lower portion of the trench 104, which includes a buried plate (BP) 110, a conformable capacitor dielectric layer 112, and a top plate 114. The buried plate 110 can be an N⁺ type doping region in the substrate 100 surrounding the lower portion of the trench 104. Moreover, the top plate 114 can be a doped polysilicon silicon layer and the capacitor dielectric layer 112 can be a stacked structure of silicon oxide/silicon nitride (ON) or silicon oxide/silicon nitride/silicon oxide (ONO). A capacitor structure of this type can be formed by a conventional method which includes the following steps. First, an N⁺ type doped dielectric layer (not shown), such as arsenic silicate glass (ASG), is conformably formed overlying the inner surface of the trench 104. Next, the trench 104 is filled with a photoresist layer (not shown) having a predetermined height. Next, the doped dielectric layer uncovered by the photoresist layer is removed by wet chemical etching, and then the photoresist layer is removed. Next, an insulating layer (not shown), such as tetraethyl orthosilicate (TEOS) oxide, is conformably formed overlying the inner surface of the trench 104 to prevent dopants from diffusing into the substrate 100 around the sidewall of the trench 104 where it is uncovered by the doped dielectric layer during subsequent annealing. Next, dopants in the doped dielectric layer are diffused in the substrate 100 by drive-in through a thermal process to form an N⁺ type doping region 110, serving as a buried plate. Next, the insulating layer and the doped dielectric layer are removed.

Next, a conformable dielectric layer (not shown) is formed overlying substrate and the inner surface of the trench 104, and then a conductive layer (not shown) is deposited overlying the substrate 100 and fills the trench 104. Thereafter, the conductive layer and the dielectric layer overlying the substrate 100 and an upper portion of the trench 104 are removed by etching to form a top plate 114 and a capacitor dielectric layer 112 in the lower portion of the trench 104.

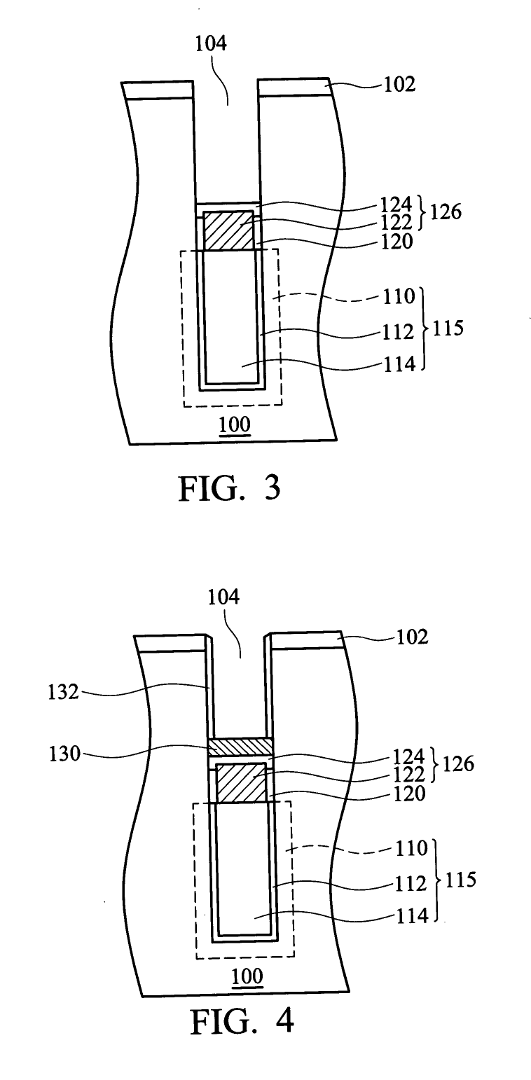

Next, in FIG. 3, an insulating layer (not shown), such as silicon oxide, is conformably deposited overlying the masking layer 102 and capacitor 115 and over the sidewall of the trench 104. Next, the insulating layer overlying the masking layer 102 and the capacitor 115 are removed by isotropic etching to form a circular insulating layer 120 over the sidewall of the trench 104 to isolate the substrate 100 and the subsequent wiring structure 126.

Next, a first conductive layer (not shown), such as doped polysilicon or doped amorphous silicon, is filled in the trench 104, and then the first conductive layer and the circular insulating layer 120 are successively etched back to a predetermined depth, so that the remaining first conductive layer 122 is surrounded by the remaining circular insulating layer 120, wherein the remaining circular insulating layer 120 in the trench 104 has a height below the remaining first conductive layer 122. Thereafter, a second conductive layer (not shown), such as polysilicon or amorphous silicon, is deposited overlying the substrate 100 and fills the trench 104. The second conductive layer is subsequently etched to leave a portion of the second conductive layer 124 to cover the first conductive layer 122 and the circular insulating layer 120. In the invention, the wiring structure 126 of the memory device is composed of the remaining first and second conductive layers 122 and 124.

Next, in FIG. 4, an insulating layer (not shown), such as high-density plasma (HDP) oxide, is conformably deposited overlying the masking layer 102 and the second conductive layer 124 and over the sidewall of the trench 104. Thereafter, etching, such as wet chemical etching, is performed to remove the insulating layer overlying the masking layer 102 and the sidewall of the trench to form a first trench top isolation layer 130 overlying the second conductive layer 124, which has a thickness of about 200 to 400 Å, and preferably 300 Å.

Next, a dielectric layer (not shown), such as silicon nitride, is deposited overlying the masking layer 102 and the first trench top isolation layer 130 and over the sidewall of the trench 104, which has a thickness of about 40 to 60 Å. Next, anisotropic etching is performed to remove the dielectric layer overlying the masking layer 102 and the first trench top isolation layer 130 to form a dielectric spacer 132 over the sidewall of the trench 104.

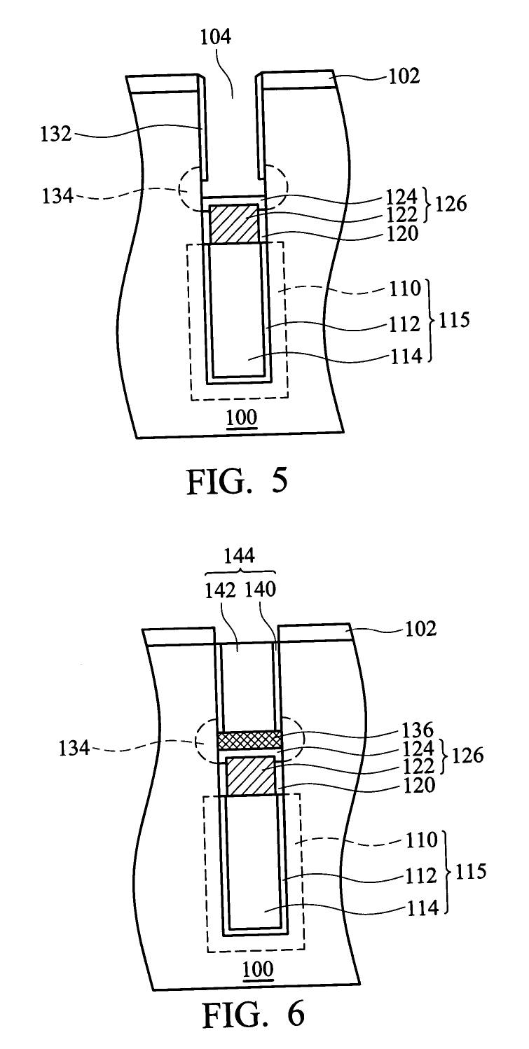

Next, in FIG. 5, the first trench top isolation layer 130 is removed by etching, for example, wet chemical etching, to expose the sidewall of the trench 104 between the dielectric spacer 132 and the second conductive layer 124. Next, gas phase doping (GPD) is performed to diffuse gas phase ions into the substrate 100 from the exposed sidewall of the trench 104 to form a buried strap 134 in the substrate 100 around the exposed sidewall of the trench 104. The dielectric spacer 132 is used as a mask to cover the other region of the sidewall of the trench 104 except the region used for buried strap formation, thereby preventing ions from diffusing into the other regions of the substrate 100. Since the ion diffusion path for forming the buried strap 134 is pre-defined by the first trench top isolation layer 130 and the dielectric spacer 132, the buried strap 134 formed in this way can more easily control the diffusion area of the ions than that formed by conventional thermal diffusion using a doped conductive layer, thereby preventing buried straps from merging.

Finally, in FIG. 6, the dielectric spacer 132 is removed by, for example, wet chemical etching, and then an insulating layer (not shown), such as a high-density plasma (HDP) oxide, is conformably deposited overlying the masking layer 102 and the second conductive layer 124 and over the sidewall of the trench 104. The insulating layer overlying the masking layer 102 and over the sidewall of the trench 104 are subsequently removed by, for example, wet chemical etching, to form a second trench top isolation layer 136 overlying the second conductive layer 124, which has a thickness of about 200 to 400 Å, and preferably 300 Å. The second trench top isolation layer 136 is used as an insulator between the subsequent control gate and the wiring structure 126.

Next, a gate oxide layer 140 and a gate conductive layer 142, such as polysilicon, tungsten-silicon alloy, metal or a combination thereof, are formed in an upper portion of the trench 104 overlying the second trench top isolation layer 136 by a conventional method. Such a method forms the gate oxide layer 140 over the sidewall of the trench 104 overlying the second trench top isolation layer 136 by thermal oxidation, and then the gate conductive layer 142 is formed in the region surrounded by the gate oxide layer 140. In the invention, the gate oxide layer 140 and the gate conductive layer 142 serve as a control gate 144 of the memory device.

According to the buried strap 134 of the invention, the diffusion area of the gas phase ions is one half of a circle, in which the upper portion is over the top surface of the second trench top isolation layer 136 and electrically connects to the control gate 144, and the lower portion electrically connects to the wiring structure 126. In the invention, the buried strap 134 is used as a drain region of the vertical transistor and used as an electrical connector between the vertical transistor and the trench capacitor.

According to the invention, the buried strap 134 formed by GPD is formed before the second trench top isolation layer 136 which serves as an insulator between the control gate 144 and the wiring structure 126. That is, the region of the electrical connection between the vertical transistor and the trench capacitor is pre-defined. Moreover, the diffusion path of gas phase ions is defined by the first trench top isolation layer 130 and the dielectric spacer 132. Accordingly, increasing the diffusion area of the buried strap in order to prevent poor electrical connection between the vertical transistor and the trench capacitor is not required. That is, the buried strap requires a smaller area than the prior art. The diameter of the diffusion area is about one half of that in the prior art, to prevent the merging of buried straps between neighboring trenches, and resulting shorts in the memory device. Moreover, the electrical connection between the vertical transistor and the trench capacitor can be effectively controlled.

In addition, since the diffusion area of the buried strap is reduced, the lateral area of the memory device can be effectively reduced compared to the prior art, thereby increasing integration of circuits.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for fabricating a memory device with a vertical transistor and a trench capacitor, comprising the steps of:
providing a substrate;
forming at least one trench in the substrate;
forming a capacitor in a lower portion of the trench;
forming a circular insulating layer over the sidewall of the trench and overlying the capacitor;
forming a wiring structure overlying the capacitor and surrounded by the circular insulating layer;
forming a first trench top isolation layer overlying the wiring structure;
forming a dielectric spacer over the sidewall of the trench and overlying the first trench top isolation layer;
removing the first trench top isolation layer to expose the sidewall of the trench between the dielectric spacer and the wiring structure;
forming a buried strap in the substrate around the exposed sidewall of the trench using the dielectric spacer as a mask to serve as a drain region;
removing the dielectric spacer;
forming a second trench top isolation layer overlying the wiring structure; and
forming a control gate overlying the second trench top isolation layer, wherein the control gate is insulated from the wiring structure by the second trench top isolation layer.

2. The method as claimed in claim 1, wherein the first and second trench top isolation layers are silicon oxide layers.

3. The method as claimed in claim 1, wherein the dielectric spacer is a silicon nitride spacer.

4. The method as claimed in claim 1, wherein the first and second trench top Isolation layers have a thickness of about 200 to 400 Å.

5. The method as claimed in claim 1, wherein the dielectric spacer has a thickness of about 40 to 60 Å.

6. The method as claimed in claim 1, wherein the first trench top isolation layer is removed by wet chemical etching.

7. The method as claimed in claim 1, wherein the buried strap is formed by gas phase doping (GPD).

8. The method as claimed in claim 1, wherein the dielectric spacer is removed by wet chemical etching.

9. The method as claimed in claim 1, wherein the buried strap is a half circular region, and the upper portion of the region electrically connects to control gate and the lower portion of that electrically connects to the wiring structure.

10. A method for fabricating a memory device with a vertical transistor and a trench capacitor, comprising the steps of:
providing a semiconductor substrate;
forming at least one trench In the semiconductor substrate;
forming a capacitor in a lower portion of the trench;
successively forming a first conductive layer and a second conductive layer overlying the capacitor to serves as a wiring structure;
forming a first trench top isolation layer overlying the wiring structure;
forming a dielectric spacer overlying the sidewall of the trench and overlving the first trench top isolation layer;
removing the first trench top isolation layer to expose the sidewall of the trench between the dielectric spacer and the wiring structure;
forming a buried strap in the substrate around the exposed sidewall of the trench using the dielectric spacer as a mask to serve as a drain region;
removing the dielectric spacer;
forming a second trench top isolation layer overlying the wiring structure; and
forming a control gate overlying the second trench top isolation layer, wherein the control gate is insulated from the wiring structure by the second trench top isolation layer.

11. The method as claimed in claim 10, wherein the first and second trench top isolation layers are silicon oxide layers.

12. The method as claimed in claim 10, wherein the dielectric spacer is a silicon nitride spacer.

13. The method as claimed in claim 10, wherein the first and second trench top isolation layers have a thickness of about 200 to 400 Å.

14. The method as claimed In claim 10, wherein the dielectric spacer has a thickness of about 40 to 60 Å.

15. The method as claimed in claim 10, wherein the first trench top isolation layer is removed by wet chemical etching.

16. The method as claimed in claim 10, wherein the buried strap is formed by gas phase doping (GPD).

17. The method as claimed in claim 10, wherein the dielectric spacer is removed by wet chemical etching.

18. The method as claimed in claim 10, wherein the buried strap is a half circular region, and the upper portion of the region electrically connects to the control gate and the lower portion thereof electrically connects to the wiring structure.

19. The method as claimed in claim 10, further forming a circular insulating layer over the sidewall of the trench and surrounding the first conductive layer.
